(19) United States
(12) Patent Application Publication
(10) Pub. No.: US 2015/0155135 A1
(43) Pub. Date: Jun. 4, 2015

(54) DRAWING APPARATUS, DRAWING METHOD, AND METHOD FOR FABRICATING ARTICLE

(71) Applicant: CANON KABUSHIKI KAISHA, Tokyo (JP)

(72) Inventor: Tatsuro Kato, Tokyo (JP)

(21) Appl. No.: 14/557,982

(22) Filed: Dec. 2, 2014

(30) Foreign Application Priority Data
Dec. 3, 2013 (JP) 2013-250402

(51) Int. Cl. H01J 37/304; H01J 37/317

(52) U.S. Cl. CPC H01J 37/304; H01J 37/3177; H01J 2237/0473; H01J 2237/0475; H01J 2237/202; H01J 2237/2487

(57) ABSTRACT

A drawing apparatus, and one or more methods, of the present invention include a data generation unit which generates drawing data representing amounts of irradiation of a beam to a plurality of unit regions on a substrate, and a beam controller which controls the beam based on a clock signal in a constant speed interval and in at least one of an acceleration interval and a deceleration interval of a stage driven while holding the substrate. The data generation unit generates drawing data based on driving data and a clock signal commonly used in the constant speed interval and in at least one of the acceleration interval and the deceleration interval. The beam controller draws a pattern on the substrate based on the drawing data.

### BACKGROUND OF THE INVENTION

1. Field of the Invention

The present inventions relate to at least one drawing apparatus, at least one drawing method, and at least one method for fabricating articles.

2. Description of the Related Art

In general, in a drawing apparatus which irradiates beams to a stage reciprocating while holding a substrate and which draws a pattern on the substrate, the pattern is drawn only while the stage is moved at a constant speed. Specifically, when the stage is decelerated, stopped, and accelerated so as to be moved in a reverse direction at a constant speed (hereinafter referred to as a “during acceleration and deceleration”), drawing is not performed, and a period of time in which drawing is not performed is required every time the stage changes a moving direction. Therefore, in recent years, a technique of performing drawing even during acceleration and deceleration has been demanded so as to improve throughput.

PCT Japanese Translation Patent Publication No. 2009-505398 discloses a technique of performing drawing even during acceleration and deceleration by changing a frequency of a clock signal which is a reference of a timing when beams are irradiated, based on a speed of a stage.

However, in the technique disclosed in PCT Japanese Translation Patent Publication No. 2009-505398, to change a frequency of a clock signal, an additional circuit for changing the clock signal is required, and accordingly, there might be a problem in that an area for circuits becomes large when compared with general techniques.

### SUMMARY OF THE INVENTION

Accordingly, the present inventions provide at least a drawing apparatus and a drawing method which are capable of drawing a pattern at least during acceleration or during deceleration of a stage without changing a frequency of a clock signal.

The present inventions provide at least one drawing apparatus including a data generation unit configured to generate drawing data representing amounts of irradiation of a beam to a plurality of unit regions on a substrate, and a beam controller configured to control the irradiation of the beam based on a clock signal in a constant speed interval and in at least one of an acceleration interval and a deceleration interval of a stage which is driven while holding the substrate. The data generation unit generates the drawing data based on driving data of the stage and the clock signal which is commonly used in the constant speed interval and in at least one of the acceleration interval and the deceleration interval, and the beam controller draws a pattern on the substrate using the drawing data. According to other aspects of the present inventions, other apparatuses and methods, including methods for fabricating articles, are discussed herein.

Further features of the present inventions will become apparent from the following description of exemplary embodiments with reference to the attached drawings.

### BRIEF DESCRIPTION OF THE DRAWINGS

FIGS. 1A and 1B are diagrams illustrating a drawing.

FIG. 2 is a diagram illustrating a configuration of a drawing apparatus according to a first embodiment.

FIG. 3 is a diagram illustrating transmission of drawing data.

FIG. 4 is a diagram illustrating arrangement of electron beams in an irradiation region.

FIG. 5 is a flowchart illustrating a process performed by a drawing data generation unit.

FIGS. 6A to 6C are diagrams illustrating generation of drawing data (constant speed interval).

FIGS. 7A and 7B are diagrams illustrating position profiles of a stage according to the first embodiment.

FIGS. 8A and 8B are diagrams illustrating generation of drawing data according to the first embodiment (acceleration interval and constant speed interval).

### DESCRIPTION OF THE EMBODIMENTS

The present invention is applicable to a drawing apparatus which draws a pattern by irradiating beam, such as electron beam, ion beam, or laser beam, on a wafer (a substrate). Hereinafter, embodiments will be described taking a drawing apparatus which draws a pattern using a plurality of electron beam while causing a stage mounted on a wafer to perform scanning as an example.

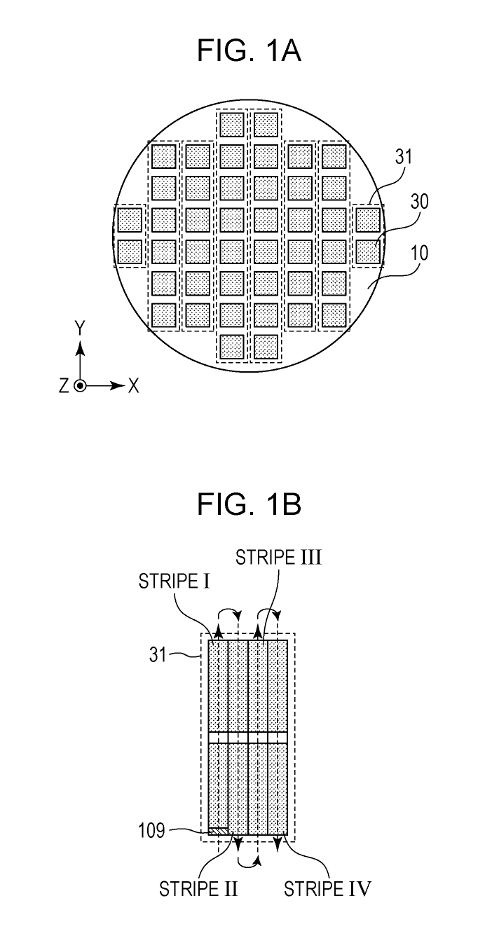

First, a general drawing method will be described with reference to FIGS. 1A and 1B. FIG. 1A is a diagram illustrating a state in which shots 30 which are regions in which patterns are drawn are arranged on a wafer 10. Each of groups of the shots 30 arranged in a Y axis direction is referred to as a shot line 31. The drawing apparatus sequentially perform drawing in an X axis direction for each shot line 31.

FIG. 1B is an enlarged view illustrating a shot line 31 including two shots 30. When a width of an irradiation region 109 is a quarter of a width of a shot 30, the shot line 31 may be divided into four stripes I to IV. When the wafer 10 performs scanning in a −Y direction in a state in which a position of the irradiation region 109 is fixed, the irradiation region 109 draws the stripe I. The wafer 10 moves in a −X direction by a width corresponding to one stripe, and thereafter, moves in a +Y direction so that the irradiation region 109 draws the stripe II. The stripes III and IV and other shot lines 31 are similarly drawn.

The drawing is performed on the shot lines 31 only in a time interval in which the wafer 10 is controlled to move at a constant speed (hereinafter referred to as a “constant speed interval”). Therefore, drawing is not performed in a period of time in which the wafer 10 changes a moving direction relative to the Y axis direction, that is, in at least one of an acceleration interval and a deceleration interval. Therefore, a period of time in which the irradiation region 109 relatively performs scanning outside a drawing region of the wafer 10 is required.

Use of drawing apparatuses according to the embodiments which execute conversion of drawing data described below enable reduction of the period of time. Accordingly, throughput is improved.

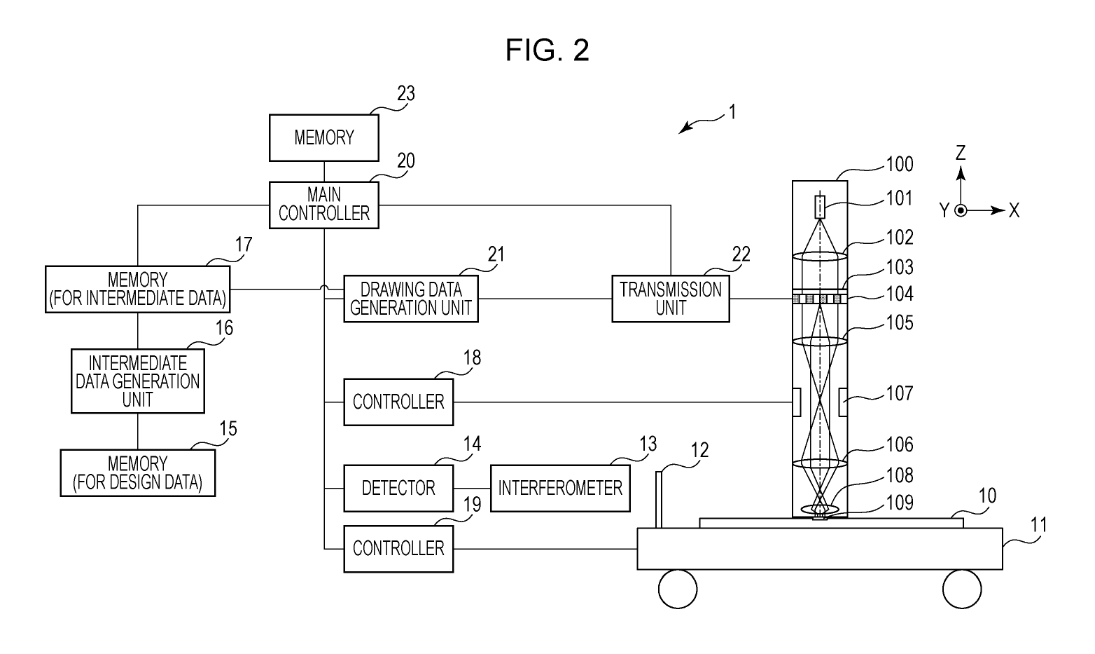

A configuration of a drawing apparatus 1 according to a first embodiment will be described with reference to FIG. 2. First, a configuration of an optical system 100 will be described. A thermionic electron source 101 uses LaB6 or BaO/W, for example, as electron emission material for emitting electron beam. The electron beam emitted from the electron source 101 are shaped into an electron flux in which the electron beam are parallel to one another by a collimator lens 102, and thereafter, the electron flux is substantially perpendicularly incident on an aperture array 103 having apertures which are two-dimensionally arranged. The aperture array 103 divides the incoming electron beam into a number of electron beams corresponding to the number of the apertures.

A modulation device 104 serving as a beam controller controls irradiation of the electron beams to the wafer 10 so that a desired pattern is drawn on the wafer 10. The modulation device 104 includes a plurality of blankers 203, which will be described hereinafter, corresponding to array of the electron beams which pass through the aperture array 103. By switching a state of a voltage to be applied to the blankers 203, switching in two levels between irradiation and non-irradiation of electron beams may be performed. In a case where a voltage is not applied, electron beams pass through the blankers 203 without change and further pass through a diaphragm (not illustrated) having openings which are two-dimensionally arranged and which correspond to the array of the electron beams. On the other hand, in a case where a voltage is applied, trajectories of the electron beams are deflected when the electron beams pass through the blankers 203 and the electron beams are blocked by the diaphragm.

The modulation device 104 controls an amount of irradiation to each pixel (unit region) in a multilevel manner by controlling the number of electron beams to be irradiated on one of pixels on the wafer 10 which is a unit irradiation region irradiated by a single electron beam.

An electrostatic lens 105 and a magnetic lens 106 form an intermediate image of the electron beams which have passed through the modulation device 104. A deflector 107 includes a pair of electrode plates for an X axis and a pair of electrode plates for a Y axis (one of the pairs is not illustrated). A magnetic lens 108 functions as an objective lens and forms an image on the wafer 10 using a plurality of electron beams in an area corresponding to the irradiation region 109.

Next, configurations of apparatuses other than the optical system 100 will be described. A supporting member (not illustrated) and the wafer 10 which is supported by the supporting member are mounted on a stage 11. A moving mirror 12 is further disposed on the stage 11.

An interferometer 13 divides an emitted laser beam into measurement light and reference light to be incident on the moving mirror 12 and a reference mirror (not illustrated) disposed in the interferometer 13, respectively. Light beams reflected by the mirrors are interfered with one another and a detector 14 detects an intensity of interference light so that a position of the moving mirror 12, that is, a position of the stage 11, is detected.

A position of a mark (not illustrated) formed on the wafer 10 is detected by an alignment optical system (not illustrated) so that arrangement of shots 30 in an existing layer is obtained and arrangement of shots 30 in a layer to be formed next is determined.

A main controller 20 is connected to the detector 14, a memory 17 for intermediate data, a controller 18, a controller 19, a drawing data generation unit (a data generation unit) 21, a transmission unit 22, and a memory 23. The main controller 20 integrally controls the components described above. For example, the main controller 20 instructs the drawing data generation unit 21 to generate drawing data in accordance with a flowchart for generating drawing data illustrated in FIG. 5 described below. Furthermore, the main controller 20 stores information in the memory 23 and obtains information from the memory 23.

Furthermore, the main controller 20 generates a clock signal for synchronizing a movement of the wafer 10 with control of irradiation of electron beams performed by the modulation device 104. The clock signal has uniform time intervals, and a clock signal having a frequency commonly used in the acceleration and deceleration interval and the constant speed interval is generated.

A memory 15 stores data on a desired drawing pattern designed by a user. An intermediate data generation unit 16 generates bitmap data in which the number of levels of electron beams to be irradiated on a single pixel is defined (hereinafter referred to as “intermediate data”). The intermediate data generation unit 16 is connected to the memory 17 and stores the generated intermediate data in the memory 17.

The controller 18 which controls the deflector 107 controls degrees of deflection of deflectors (not illustrated) for the X and Y axes included in the deflector 107. The deflector 107 may independently control the deflectors for the X and Y axes. When a relative position between the irradiation region 109 and the wafer 10 is shifted from a preset irradiation position, the deflector 107 corrects the irradiation position by collectively shifting irradiation positions of electron beams.

The controller 19 moves the stage 11 in X, Y, and Z directions base on positional information of the stage 11 supplied from the detector 14 and the clock signal transmitted from the main controller 20. The constant speed interval representing a time interval in which the stage 11 is driven in accordance with an instruction for driving the stage 11 at a constant speed issued by the controller 19. Note that an actual speed may include a little error relative to a predetermined speed instruction value. In the acceleration and deceleration interval, the stage 11 is driven in response to an instruction for driving the stage 11 at a predetermined acceleration speed issued by the controller 19.

The drawing data generation unit 21 obtains the intermediate data stored in the memory 17 and converts the intermediate data into drawing data. The drawing data represents amounts of irradiation of beams on a plurality of unit regions, and represents the relationship among a position of a pixel, electron beams irradiated to the pixel, and an irradiation time represented by a clock signal. Since electron beams are controlled by the two levels including irradiation and non-irradiation, an amount of irradiation to each of the pixels is represented by a combination of an irradiation ON instruction (irradiation data) and an irradiation OFF instruction (non-irradiation data).

The transmission unit 22 transmits the clock signal supplied from the main controller 20 and the drawing data generated by the drawing data generation unit 21 to the modulation device 104. The memory 23 stores a driving data representing a relationship between a time and a driving state of the stage 11. The driving data represents the relationship between a time and at least one of acceleration, a speed, and a position of the stage 11.

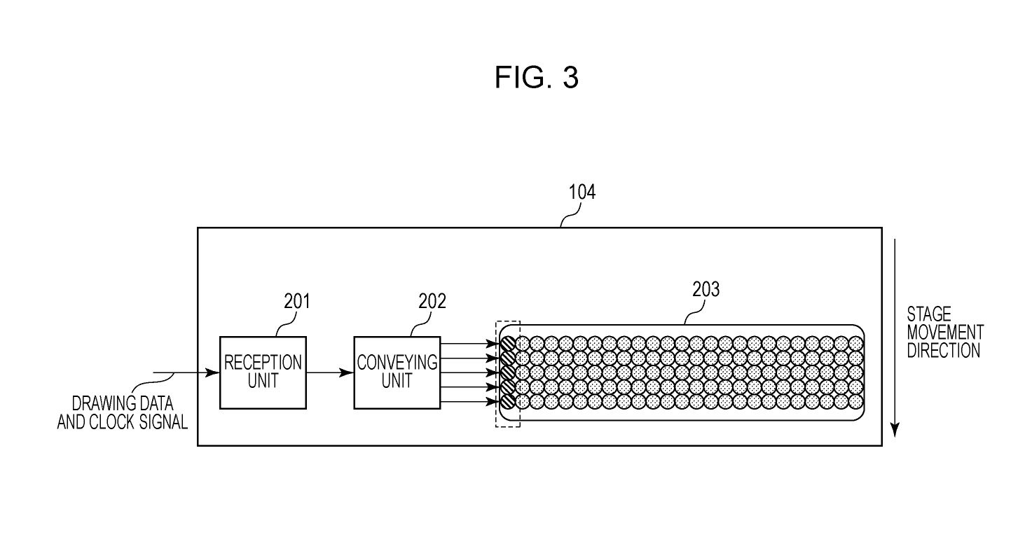

FIG. 3 is a diagram illustrating a configuration of the modulation device 104 in detail. The modulation device 104 includes a reception unit 201, a conveying unit 202 for conveying drawing data, and the blankers 203 in a matrix of 5 rows and 25 columns. The reception unit 201, the conveying unit 202, and the blankers 203 are integrally configured on a single IC chip. The reception unit 201 receives the drawing data and the clock signal which are supplied from the transmission unit 22 and transmits the drawing data and the clock signal to the conveying unit 202. The conveying unit 202 transmits an irradiation ON instruction and an irradiation OFF instruction to the blankers 203 in synchronization with timings of the clock signal so that irradiation is performed on predetermined pixels by a predetermined irradiation amount at a timing included in the generated drawing data.

A drawing method of this embodiment will be described. Before drawing is performed, the drawing data generation unit 21 generates drawing data to be transmitted to the modulation device 104. Since drawing is performed on the wafer 10 on the basis of the generated drawing data, a method for generating drawing data will be mainly described. In this embodiment, drawing data in the acceleration and deceleration interval and the constant speed interval of the stage 11 is generated on the basis of a driving state of a case where drawing is performed only in the constant speed interval and drawing data of the case where drawing is performed only in the constant speed interval. The memory 23 stores driving data representing the driving state of the stage 11 in the case where all the shots 30 on the wafer 10 are drawn only in the constant speed interval.

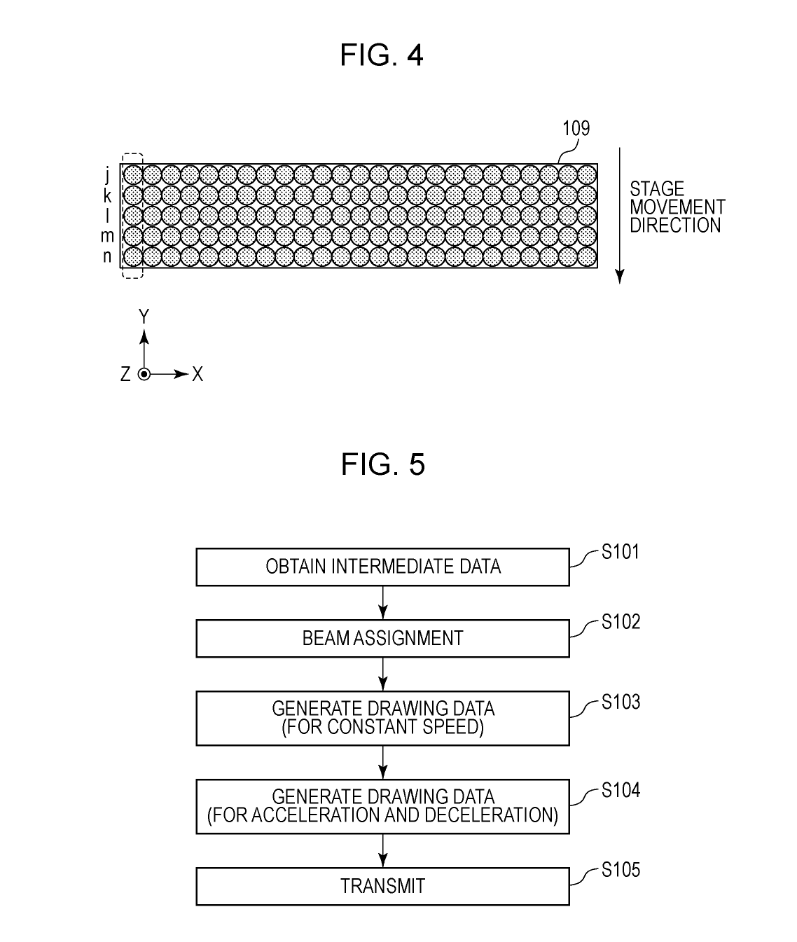

FIG. 4 is an enlarged view of the irradiation region 109 formed on the wafer 10. When an instruction for irradiating all electron beams is issued, the drawing apparatus 1 irradiates the electron beams on the wafer 10 using 125 electron beams, that is, electron beams in a matrix of 5 rows and 25 columns which is the same as the matrix of the blankers 203. Assuming that a driving direction of the stage 11 is −Y direction, at most five electron beams may be irradiated on a single pixel on the wafer 10. Since the total number of electron beams which may be irradiated to a single pixel corresponds to a total irradiation amount, the modulation device 104 may control an irradiation amount by six levels from 0 to 5. The electron beams irradiated on a single pixel on the wafer 10 which moves in the −Y direction are referred to as electron beams in j-th, k-th, l-th, m-th, and n-th rows in an order of irradiation.

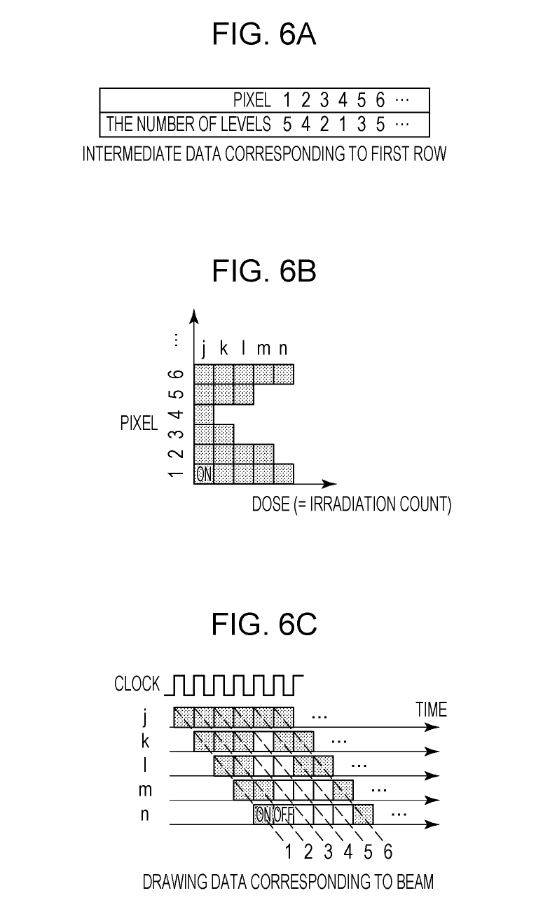

A flowchart of a process of generating drawing data executed by the drawing data generation unit 21 in response to an instruction issued by the main controller 20 is illustrated in FIG. 5. First, in step S101, the drawing data generation unit 21 obtains intermediate data stored in the memory 17. The intermediate data is illustrated in FIG. 6A. In FIG. 6A, numbers of levels of irradiation to pixels of Nos. 1 to 6 which are sequentially subjected to irradiation of beams in the j-th to the n-th rows in the first column of the irradiation regions 109 are illustrated.

In step S102 of FIG. 5, data representing assignment of beams for irradiation is generated on the basis of the intermediate data. FIG. 6B is a diagram illustrating the beam assignment data. The beam assignment data represents the relationships between the pixels and beams to be irradiated which satisfy irradiation amounts in the intermediate data. Although priority levels of electron beams to be irradiated are determined in order of j to n in FIG. 6B, other methods which determine the priority levels may be employed.

Referring back to FIG. 5, the drawing data generation unit 21 generates drawing data (virtual drawing data) in a case where drawing is performed only in the constant speed interval in step S103. FIG. 6C is a diagram illustrating drawing data in the case where the stage 11 performs drawing only in the constant speed interval. In FIG. 6C, the irradiation ON instruction and the irradiation OFF instruction of the electron beams in the j-th to n-th rows in the first column relative to a time axis represented by a clock signal are illustrated. A clock signal for irradiation control and a clock signal for the movement of the stage 11 are synchronized with each other, and a period of time required for movement of the stage 11 by one pixel in the constant speed interval of the stage 11 is determined as one clock.

For example, the pixel of No. 1 is subjected to irradiation of electron beams of the j-th row at a time point T1, and thereafter, the pixel of No. 2 is subjected to the irradiation of the electron beams of the j-th row at a time point T2 after one clock. Electron beams in the k-th row irradiate the pixel of No. 1 at the time point T2 which has moved in a position shifted by one pixel. Drawing data of the other 24 columns is also generated by the same method.

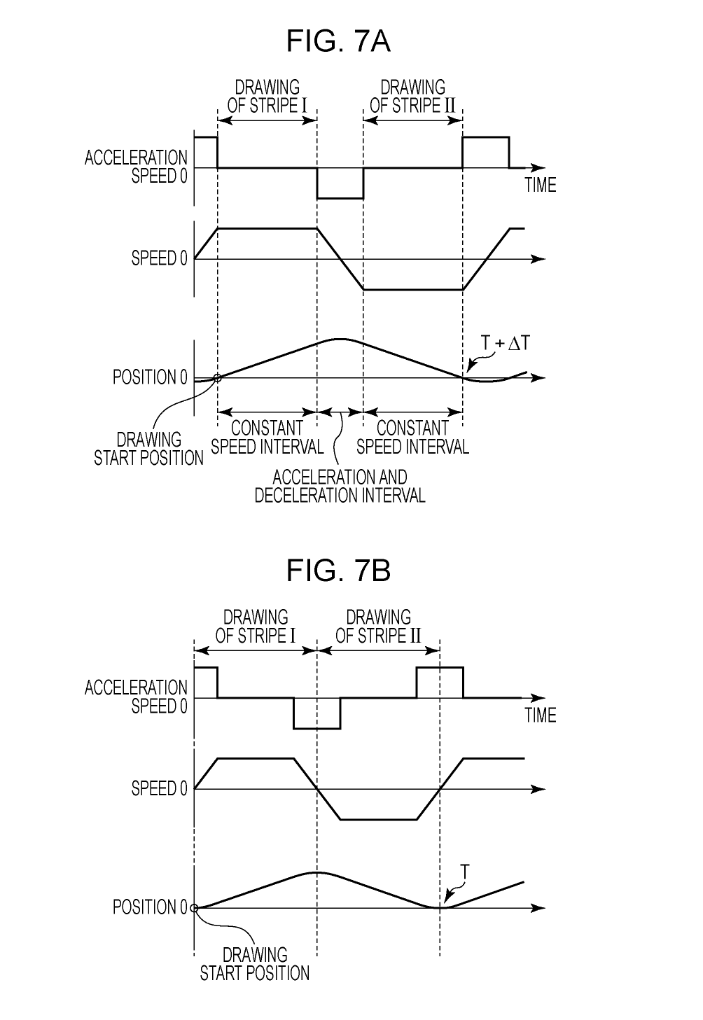

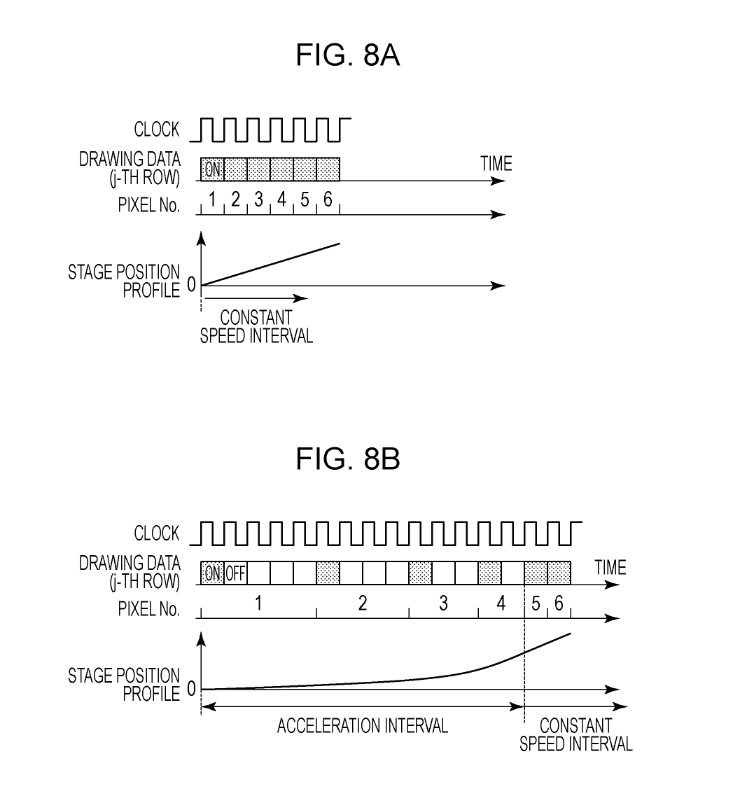

In step S104 of FIG. 5, drawing data used in a case where drawing is performed also in the acceleration and deceleration interval of the stage 11 is generated on the basis of the drawing data generated in step S103. In step S104 of the flowchart in FIG. 5, drawing data used to perform drawing also in the acceleration and deceleration interval is generated. Content of the process in step S104 will be described with reference to FIGS. 7A, 7B, 8A and 8B. FIGS. 7A and 7B are diagrams illustrating the relationships among acceleration, a speed, a position of the stage 11, and a time in a case where drawing is performed on the stripe I and the stripe II which is adjacent to the stripe I. Hereinafter, the relationship between a time and a position of the stage 11 is referred to as a position profile. Note that a position 0 represents an end of a shot line 31 serving as a start point of a drawing region.

FIG. 7A is a graph in a case where the stage 11 performs drawing only in the constant speed interval, and FIG. 7B is a graph in a case where the stage 11 performs drawing in both of the acceleration and deceleration interval and the constant speed interval. Since drawing is performed also in the acceleration and deceleration interval, a period of time required for drawing the stripes I and II may be reduced by ΔT. Here, “ΔT” denotes a period of time required for one acceleration and deceleration interval.

A drawing data conversion method executed by the drawing data generation unit 21 will be described taking drawing data corresponding to the electron beams in the j-th row in the first column of the blankers 203 as an example with reference to FIGS. 8A and 8B. In the drawing data conversion method described below, the drawing data generated in step S103 is converted taking a fact that the number of clock signals required for movement by one pixel in the acceleration and deceleration interval is larger than that in the constant speed interval into consideration. According to this conversion method, drawing results in the cases of FIGS. 7A and 7B are the same as each other based on a clock signal commonly used in the acceleration and deceleration interval and the constant speed interval.

FIG. 8A is a diagram illustrating a position profile of the stage 11 in the constant speed interval and the drawing data in the j-th row in the first column generated in step S103. FIG. 8B is a diagram illustrating a position profile in the acceleration interval and drawing data in the j-th row in the first column in a case where drawing is performed in the acceleration interval. Conversion of the drawing data is performed by a procedure described below using the position profile of FIG. 7A.

First, a period of time required for movement by one pixel is obtained from the position profile of the stage 11 in the acceleration interval of FIG. 7A, and thereafter, the number of cycles of a clock signal corresponding to the period of time (the number of cycles of a clock signal corresponding to the period of time required for movement by a unit region) is obtained. As illustrated in FIG. 8B, in this embodiment, the pixel of No. 1 requires five clocks, the pixel of No. 2 requires four clocks, the pixel of No. 3 requires three clocks, and the pixel of No. 4 requires two clocks, and the pixel of No. 5 which enters the constant speed interval and the following pixels require one clock each. Similarly, a period of time required for movement by one pixel and the number of cycles of a clock signal corresponding to the period of time are obtained also in the deceleration interval.

Next, in a case where N clocks (N is a natural number equal to or larger than 2) is required for movement by one pixel, the drawing data generation unit 21 adds (N-1) irradiation OFF instructions to drawing data of the pixel so that an amount of irradiation of electron beams is not changed even in the acceleration and deceleration interval.

In this embodiment, four irradiation OFF data items are added to the pixel of No. 1, three to the pixel of No. 2, two to the pixel of No. 3, and one to the pixel of No. 4. By this, drawing data illustrated in FIG. 8B is obtained. A position of an ON data item corresponding irradiation may correspond to any timing when N clocks (N is an integer equal to or larger than 2) are required for movement by one pixel. The numbers of irradiation ON data items of individual pixels are not changed before and after the conversion from FIG. 8A to FIG. 8B.

If the stage 11 moves by n pixels (four pixels in this embodiment) in total in the acceleration interval and moves by n pixels also in the deceleration interval, an amount of movement in the constant speed interval is reduced by 2n pixels in total. Therefore, in the constant speed interval, drawing data is generated by reducing drawing data by 2n clocks. Furthermore, the drawing data conversion process is performed in the deceleration interval similarly to the acceleration interval. By the process described above, drawing data may be generated in a case where drawing is performed even in the acceleration and deceleration interval. Note that the same method is employed for conversion of drawing data relative to blankers 203 disposed in positions other than the j-th row in the first column, and therefore, a description thereof is omitted.

Finally, the drawing data generation unit 21 transmits the drawing data generated in step S105 to the transmission unit 22. In order to enable drawing even in the acceleration and deceleration interval, a position profile in which a period of time in the constant speed interval is reduced is additionally required. The position profile is generated by the main controller 20, the controller 19 which controls the stage 11, or the like.

The method for drawing a pattern in accordance with the drawing data in the acceleration and deceleration interval and the constant speed interval of the stage 11 which is generated based on the driving state of the stage 11 in the general drawing method and the drawing data is described above.

The drawing data generation unit 21 generates drawing data on the basis of drawing data used when drawing is performed only in the constant speed interval, driving data in at least one of the acceleration interval and the deceleration interval, and a clock signal. First, the drawing data generation unit 21 obtains a period of time required for movement of the stage 11 by one pixel in at least one of the acceleration interval and the deceleration interval and obtains the number of cycles of a clock signal corresponding to the period of time. Next, the drawing data generation unit 21 determines an amount of data of irradiation OFF instructions for the target pixel from the obtained number of cycles of the clock signal and generates drawing data on the basis of the data amount. Specifically, the drawing data generation unit 21 generates drawing data in a case where a certain pixel is drawn in the acceleration and deceleration interval, using a larger number of non-irradiation OFF instructions relative to a case where the target pixel is drawn in the constant speed interval.

In this embodiment, since drawing data is generated in the acceleration interval and the deceleration interval by the method described above, a pattern may be drawn by reducing a period of time by approximately (ΔT/2)×(a period of time corresponding to the number of stripes) relative to the single wafer 10. Furthermore, since drawing data is converted without changing a frequency of a clock signal, a circuit area for changing a frequency of a clock signal may be effectively eliminated.

In a second embodiment, in step S104, drawing data for performing drawing even when acceleration or deceleration is performed is directly generated using intermediate data illustrated in FIG. 6A and a position profile in a case where drawing is performed in the acceleration and deceleration interval illustrated in FIG. 7B. The memory 23 stores driving data indicating a driving state of the stage 11 in a case where drawing is performed in the acceleration and deceleration interval and the constant speed interval (FIG. 7B). The second embodiment is different from the first embodiment in that drawing data generated by a general method (FIG. 6C) and a general position profile of a general stage 11 (FIG. 7A) are not required.

Hereinafter, a method for generating drawing data corresponding to pixels of Nos. 1 to 6 which are arranged in a +Y direction in a first column from the left of FIG. 4 will be described as an example. Note that, as for irradiation of electron beams in a j-th row to an n-th row in six levels in total, electron beams are used in priority order of the j-th row, the k-th row, the l-th row, the m-th row, and the n-th row. Processing contents in steps S101 and S105 illustrated in the flowchart of FIG. 5 are the same as those of the first embodiment, and therefore, descriptions thereof are omitted.

First, a period of time required for movement by one pixel is obtained from a position profile illustrated in FIG. 7B. Thereafter, the number of clocks corresponding to the period of time is calculated. It is assumed that, as a result of the calculation, the numbers of clocks required for movements of the pixels Nos. 1 to 6 are 5, 4, 3, 2, 1, and 1, respectively.

Irradiation OFF data (16 data items in total in this embodiment) is assigned to numbers of data items corresponding to the numbers of clocks required for movement of all the pixels. Subsequently, positions of irradiation ON data of electron beams are determined using intermediate data indicating the numbers of levels of irradiation to be performed on the pixels.

Since electron beams are preferentially used in an order from the j-th row to the n-th row, beams in the j-th row are used at any time when the number of levels is 1 or more. Furthermore, electron beams in the k-th row are used at any time when the number of levels is 2 or more. Similarly, as for electron beams in the l-th row, the m-th row, and the n-th row, a determination as to whether electron beams in each of the l-th row, the m-th row, and the n-th row are irradiated is made using the numbers of levels of irradiation to be performed on the pixels.

In a pixel determined to be subjected to irradiation in a certain row, an irradiation OFF instruction by one clock is replaced by an irradiation ON instruction. Specifically, OFF data is replaced by ON data by one clock in each of the pixels of No. 1 to 6 in the j-th row, and OFF data is replaced by ON data by one clock in pixels other than the pixel of No. 4 (the number of levels is 1) in the k-th row. The data replacement is similarly performed on electron beams in the l-th row, the m-th row, and the n-th row.

Since the replacement is performed on all pixels in the wafer 10, that is, the pixels in a matrix of 5 rows and 25 columns, drawing data which may be drawn even in the acceleration and deceleration may be generated. By this, as with the first embodiment, since drawing is performed even during the acceleration and during deceleration, a period of time in which the stage 11 performs scanning may be reduced when compared with the related art, and accordingly, throughput is improved. Note that, when a number of electron beams in the j-th row to the n-th row are likely to be difficult to be controlled, drawing data is generated by appropriately changing priority levels of electron beams to be used.

Also in the second embodiment, drawing data which enables drawing in the acceleration and deceleration interval is generated using data indicating an amount of electron beams to be irradiated on a pixel, driving data, and a clock signal which is commonly used in the acceleration and deceleration interval and the constant speed interval. Therefore, a circuit for changing a frequency of a clock signal is not required, and furthermore, throughput may be improved since drawing is performed even in the acceleration and deceleration interval.

### Other Embodiment

Although drawing is performed on the wafer 10 using a plurality of electron beams in the forgoing embodiments, the drawing data generation method and the drawing method are applicable to a case where a pattern is drawn by a single electron beam. Arrangement of the blankers 203 in the modulation device 104 is also merely an example, and the arrangement may be appropriately changed. Furthermore, when an amount of irradiation of electron beams for one clock has multilevel, drawing data which reduces the irradiation amount to 1/N when a period of time in which the stage 11 moves by one pixel is N clock may be generated.

Furthermore, a modulation device is not limited to the modulation device 104, and other devices having other configurations in which amounts of irradiation of electron beams and irradiation/non-irradiation may be individually controlled based on generated drawing data may be used.

An initial position and a drawing start position in the position profile of the wafer 10 associated with generated drawing data may not coincide with each other unlike the position profile illustrated in FIG. 7B. If drawing is performed during acceleration and deceleration of the stage 11 without changing a clock signal, even when an initial position of the wafer 10 in the associated position profile is not 0, throughput may be effectively improved. Furthermore, only by changing drawing data so that drawing is performed during acceleration or during deceleration, throughput is improved.

If a clock signal used for movement of the stage 11 is synchronized with a clock signal indicating a timing of control of drawing data, instead of the common clock signal generated by the main controller 20, a clock signal generated another portion may be used.

Furthermore, the drawing apparatus 1 preferably has a plurality of optical systems 100, and a drawing pattern is preferably stored in the memory 23 through the main controller 20 so that the same drawing pattern is applied to all wafers in the same lot. In this way, throughput may be improved.

A method for fabricating articles (a semiconductor integrated circuit element, a liquid crystal display element, a CD-RW (compact disc rewritable), and a mask for optical exposure apparatus) of the present invention includes a step of drawing a pattern on a substrate, such as an Si wafer or a glass, using the drawing apparatus 1 and a step of developing the substrate including the pattern drawn thereon. Furthermore, other general steps (oxidation, film formation, deposition, doping, flattening, etching, resist removing, dicing, bonding, packaging, and the like) may be included.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-250402, filed Dec. 3, 2013, which is hereby incorporated by reference herein in its entirety.

What is claimed is:

1. A drawing apparatus comprising:
a data generation unit configured to generate drawing data representing amounts of irradiation of a beam to a plurality of unit regions on a substrate; and
a beam controller configured to control the irradiation of the beam based on a clock signal in a constant speed interval and in at least one of an acceleration interval and a deceleration interval of a stage which is driven while holding the substrate,
wherein the data generation unit generates the drawing data based on driving data of the stage and the clock signal which is commonly used in the constant speed interval and in at least one of the acceleration interval and the deceleration interval, and the beam controller draws a pattern on the substrate using the drawing data.

2. The drawing apparatus according to claim 1, wherein
the irradiation amounts are represented by a combination of irradiation data and non-irradiation data, and
the data generation unit generates the drawing data using a larger amount of the non-irradiation data for the unit regions drawn in at least one of an acceleration interval and a deceleration interval than the non-irradiation data for the unit regions in the constant speed interval.

3. The drawing apparatus according to claim 1, wherein
the data generation unit obtains periods of time required for movement of the stage by the corresponding unit regions in at least one of the acceleration interval and the deceleration interval.

4. The drawing apparatus according to claim 1, wherein
the data generation unit generates the drawing data using a number or numbers of cycles of the clock signal corresponding to periods of time required for movement by the corresponding unit regions.

5. The drawing apparatus according to claim 2, wherein
the data generation unit determines amounts of the non-irradiation data in the unit regions to be drawn in at least one of the acceleration interval and the deceleration interval based on a number or numbers of cycles of the clock signal corresponding to periods of time required for movement by the corresponding unit regions.

6. The drawing apparatus according to claim 1, wherein
the driving data represents the relationship between a time and at least one of acceleration, a speed, and a position of the stage.

7. The drawing apparatus according to claim 1, wherein
the data generation unit generates the drawing data based on virtual drawing data obtained when the unit regions to be drawn in at least one of the acceleration interval and the deceleration interval are drawn in the constant speed interval, driving data in at least one of the acceleration interval and the deceleration interval, and the clock signal.

8. The drawing apparatus according to claim 1, wherein
the data generation unit generates the drawing data based on data representing amounts of irradiation to be performed to the unit regions, the driving data, and the clock signal.

9. A drawing apparatus comprising:
a data generation unit configured to generate drawing data including data representing amounts of irradiation of a beam to a plurality of unit regions on a substrate by a combination of irradiation data and non-irradiation data; and
a beam controller configured to control the irradiation of the beam,
wherein the data generation unit generates the drawing data using a larger amount of the non-irradiation data for the unit regions drawn in at least one of an acceleration interval and a deceleration interval of a stage driven while holding the substrate than the non-irradiation data for the unit regions in the constant speed interval, and the beam controller draws a pattern on the substrate based on the drawing data.

10. A drawing method for drawing a pattern by irradiating beam on a substrate, the method comprising:
generating drawing data representing amounts of irradiation of the beam to unit regions on the substrate based on driving data of a stage which is driven while holding the substrate and a clock signal which is commonly used in a constant speed interval and in at least one of an acceleration interval and a deceleration interval of the stage; and
drawing in the constant speed interval and in at least one of the acceleration interval and the deceleration interval based on the drawing data.

11. A method for fabricating articles comprising:
irradiating beam on the substrate using a drawing apparatus which includes
a data generation unit configured to generate drawing data representing amounts of irradiation of the beam to a plurality of unit regions on a substrate, and
a beam controller configured to control the irradiation of the beam based on a clock signal in a constant speed interval and in at least one of an acceleration interval and a deceleration interval of a stage which moves while holding the substrate,
wherein the data generation unit generates the drawing data based on driving data of the stage and the clock signal commonly used in the constant speed interval and in at least one of the acceleration interval and the deceleration interval, and the beam controller draws a pattern on the substrate based on the drawing data; and
developing the substrate.
